(19) United States
(12) Patent Application Publication
(10) Pub. No.: US 2025/0318242 A1
(43) Pub. Date: Oct. 9, 2025

(54) METHOD FOR FABRICATING PATTERN AND METHOD FOR FABRICATING SEMICONDUCTOR DEVICE USING THE SAME

(71) Applicant: SK hynix Inc., Gyeonggi-do (KR)

(72) Inventor: You Song KIM, Gyeonggi-do (KR)

(21) Appl. No.: 18/827,860

(22) Filed: Sep. 9, 2024

(30) Foreign Application Priority Data
Apr. 4, 2024 (KR) 10-2024-0045824

(51) Int. Cl. H01L 29/423; H01L 21/033

(52) U.S. Cl. CPC H10D 64/513; H01L 21/0337

(57) ABSTRACT

A semiconductor device includes an isolation layer defining a plurality of active regions in first and second directions; a plurality of trenches of a wave-shaped pattern extending in the first direction to cross the active regions and the isolation layer, the plurality of trenches being spaced apart from each other in the second direction; and a buried gate structure gap-filling the trenches, wherein the trenches correspond to the active regions and each active region is disposed one trench.

### CROSS-REFERENCE TO RELATED APPLICATIONS

The present application claims priority under 35 U.S.C 119(a) to Korean Patent Application No. 10-2024-0045824, filed on Apr. 4, 2024, which is incorporated herein by reference in its entirety.

### BACKGROUND

### 1. Field

Various embodiments of the present invention relate generally to semiconductor technology and, and more particularly, to a method for forming a fine pattern in a semiconductor device.

### 2. Description of the Related Art

As semiconductor devices become smaller and more highly integrated, methods for forming fine patterns are being developed. For the existing photolithography process, new exposure equipment is being developed to form the fine patterns, but there are limitations in forming the patterns with a line width below a predetermined critical dimension. Hence new methods are needed.

### SUMMARY

Embodiments of the present invention are directed to a method for forming a pattern that may decrease process difficulty and secure process margin, and a method for fabricating a semiconductor device using the same.

In accordance with an embodiment of the present invention, a semiconductor device includes an isolation layer defining a plurality of active regions in first and second directions; a plurality of trenches of a wave-shaped pattern extending in the first direction to cross the active regions and the isolation layer, the plurality of trenches being spaced apart from each other in the second direction; and a buried gate structure gap-filling the trenches, wherein the trenches correspond to the active regions and each active region is disposed one trench.

In accordance with another embodiment of the present invention, a method for fabricating a semiconductor device includes forming an isolation layer and an active region defined by the isolation layer over a substrate; forming a wave-shaped sacrificial pattern extending in a first direction over the substrate; forming sacrificial spacers on both sides of the sacrificial pattern; forming a hard mask pattern to gap-fill between the sacrificial spacers; removing the sacrificial spacers; forming a trench crossing the isolation layer and the active region in the first direction and disposed at a center of each active region by using the hard mask pattern as an etch barrier and etching the substrate; and forming a buried gate structure to gap-fill the trench.

In accordance with another embodiment of the present invention, a method for fabricating a semiconductor device includes forming an isolation layer and an active region defined by the isolation layer over a substrate; forming a wave-shaped sacrificial pattern extending in a first direction over the substrate; forming spacers on both sides of the sacrificial pattern; forming a trench crossing the isolation layer and the active region in the first direction and disposed at a center of each active region by using the spacers as an etch barrier and etching the substrate; and forming a buried gate structure gap-filling the trench.

In accordance with another embodiment of the present invention, a method for forming a pattern includes sequentially forming a first hard mask layer and a second hard mask layer over an etch target layer; forming a first mask pattern that defines a first hole pattern over the second hard mask layer; etching a second hard mask layer by using the first mask pattern as an etch barrier; forming a planarization layer over the etched second hard mask layer; forming a second mask pattern that defines a second hole pattern having the same shape as a shape of the first hole pattern and partially overlapping with the first hole pattern in a first direction over the planarization layer; forming a second hard mask pattern having a wave-shaped pattern by using the second mask pattern as an etch barrier and etching the planarization layer and the second hard mask layer; etching the first hard mask layer by using the second hard mask pattern as an etch barrier; and forming a fine wave-shaped pattern by using the etched first hard mask layer as an etch barrier and etching the etch target layer.

In accordance with another embodiment of the present invention, a method for fabricating a semiconductor device includes forming an isolation layer and an active region defined by the isolation layer over a substrate; forming a wave-shaped sacrificial pattern extending in a first direction over the substrate; forming sacrificial spacers on both sides of the sacrificial pattern; forming spacers on both sides of the sacrificial spacer; forming a trench crossing the isolation layer and the active region in the first direction and disposed at a center of each active region by using the spacer as an etch barrier and etching the substrate; and forming a buried gate structure to gap-fill the trench.

These and other features and advantages of the embodiments of the present invention will become apparent to those skilled in the art from the following detailed description in conjunction with the following drawings.

### BRIEF DESCRIPTION OF THE DRAWINGS

FIGS. 1A and 1B are a plan view and a cross-sectional view illustrating a semiconductor device having a wave-shaped pattern in accordance with an embodiment of the present invention.

FIGS. 2A, 3A, 4A, 5A, 6A, 7A, 8A, 9A, 10A, 11A, 12A, 13A, 14A and 15A are plan views illustrating a method for fabricating a semiconductor device having a wave-shaped pattern in accordance with an embodiment of the present invention.

FIGS. 2B, 3B, 4B, 5B, 6B, 7B, 8B, 9B, 10B, 11B, 12B, 13B, 14B and 15B are cross-sectional process views illustrating a method for fabricating a semiconductor device having a wave-shaped pattern in accordance with an embodiment of the present invention.

FIGS. 16A to 16F are plan views illustrating a method for forming a wave-shaped pattern in accordance with another embodiment of the present invention.

FIGS. 17A to 17G are plan views illustrating a method for forming a wave-shaped pattern in accordance with another embodiment of the present invention.

FIGS. 18A to 18G are plan views illustrating a method for forming a wave-shaped pattern in accordance with another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout this disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The present invention is described herein with reference to cross-section and/or plan illustrations of embodiments of the present invention. However, the embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

It should be understood that the drawings are simplified schematic illustrations of the described devices and may not include well known details to avoid obscuring the features of the invention.

It should also be noted that features present in one embodiment may be used with one or more features of another embodiment without departing from the scope of the invention.

It is further noted, that in the various drawings, like reference numbers designate like elements.

As used herein, singular forms are intended to include the plural forms as well, unless the context clearly indicates otherwise.

Unless otherwise defined, all terms including technical and scientific terms used herein have the same meaning as commonly understood by one of ordinary skill in the art.

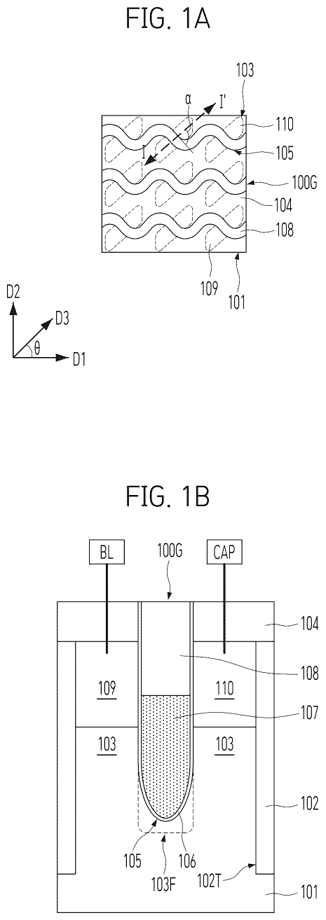

FIGS. 1A and 1B are a plan view and a cross-sectional view illustrating a semiconductor device having a wave-shaped pattern in accordance with an embodiment of the present invention. FIG. 1A is a plan view and FIG. 1B is a cross-sectional view taken along a line I-I′ shown in FIG. 1A.

Referring to FIGS. 1A and 1B, the semiconductor device in accordance with an embodiment of the present invention may include a substrate 101, a buried gate structure 100G embedded in the substrate 101, a first doped region 109, and a second doped region 110. The first and second doped regions 109 and 110 may be formed on either side of the buried gate structure 100G, respectively. The buried gate structure 100G and the first and second doped regions 109 and 110 may form a cell transistor. The cell transistor may alleviate a short channel effect due to the buried gate structure.

The semiconductor device 100 may be part of a memory cell. For example, the semiconductor device 100 may be part of a memory cell of a Dynamic Random Access Memory (DRAM). The semiconductor device 100 may include a bit line BL and a memory storage element CAP that are electrically connected to the substrate 101. The bit line BL may be electrically connected to the first doped region 109, and the memory storage element CAP may be electrically connected to the second doped region 110. The bit line BL and the memory storage element CAP may be disposed at a higher level than the buried gate structure 100G. The bit lines BL and the memory storage elements CAP may be disposed at different levels. The memory storage element CAP may be disposed at a higher level than the bit line BL. The memory storage element CAP may include a capacitor. According to another embodiment of the present invention, the memory storage element CAP may be a thyristor, a phase-change material, a Magnetic Tunnel Junction (MTJ), or a variable resistance material.

An isolation layer 102 and active regions 103 may be formed over the substrate 101. The active regions 103 may be defined by the isolation layer 102. The isolation layer 102 may be a Shallow Trench Isolation (STI) region that is formed by a trench etching process. The isolation layer 102 may be formed by filling a shallow trench, for example, an isolation trench 102T, with a dielectric material. The isolation layer 102 may include silicon oxide, silicon nitride, or a combination thereof.

The active regions 103 may be formed of strips and may be arranged as an array. The array of active regions 103 may include a row array and/or a column array. The row array of active regions 103 may include active regions 103 that are arranged in a first direction D1. The column array of active regions 103 may include active regions 103 that are arranged in a second direction D2. Each the active region 103 may include a long axis and a short axis. A long axis direction of the active regions 103, which is a third direction D3, may be non-orthogonal to the first direction D1 and the second direction D2 in order to form an intersection angle “θ”. The intersection angle “θ” between the first direction D1 and the third direction D3 of each active region 103 may range from approximately 10° to 80°, but the embodiments of the present invention are not limited thereto. The range of the intersection angle “θ” may be affected by parameters such as the area of each active region 103, the line width of the bit line, and the line width of the buried gate structure 100G. From the perspective of a top view, the horizontal cross-section of each active region 103 may be a parallelogram, for example, a parallelogram with rounded edges.

The active regions 103 may be arranged in a unidirection of the third direction D3.

A trench 105 may be formed in the substrate 101. The trench 105 may be formed by using the hard mask layer 104 as an etch barrier and etching the substrate 101. From the perspective of the top view of

FIG. 1A, the trench 105 may have a wave-shaped pattern extending in the first direction D1. The trench 105 may be a wave-shaped pattern crossing the active regions 103 and the isolation layer 102. One trench 105 may be formed in each active region 103.

The trench 105 may extend in the first direction with a uniform line width. The trench 105 may cross each active region 103 in a short axis direction. To be specific, the trench 105 may cross the center of each active region 103 based on the long axis direction of each active region 103. Accordingly, the areas of both sides of the trench 105 in each active region 103, that is, the area of the first doped region 109 and the area of the second doped region 110, may be the same, but the embodiments of the present invention are not limited thereto.

The wave-shaped pattern of the trench 105 may have a tilting angle α that may maximize the areas of the first and second doped regions 109 and 110. The tilting angle a refers to the angle between the wave-shaped pattern crossing the short axis of each active region 103 and the long axis direction of each active region 103. According to this embodiment of the present invention, to facilitate identification, the angle between the indicator line extending from the wave-shaped pattern crossing the short axis of each active region 103 and the I-I′ direction line illustrated to be parallel to the long axis direction of the active region 103 may be denoted as a tilting angle α. For example, the wave-shaped pattern of the trench 105 overlapping with each active region 103 may have a tilting angle α of approximately 45° to 135° based on the long axis of each active region 103.

The trenches 105 may be spaced apart from each other in the second direction D2. The trench 105 may have a shallower depth than the isolation trench 102T. The bottom portion of the trench 105 may have a curvature. The trench 105 may be a space where the buried gate structure 100G is formed, and the trench 105 may also be referred to as a ‘gate trench 105’.

A fin 103F may be formed below the trench 105. The fin 103F may be formed by additionally etching the bottom surface of the trench 105 of the isolation layer 102 to create a height difference between the bottom surface of the trench 105 of the active region 103 and the bottom surface of the trench 105 of the isolation layer 102. The fin 103F may be called a saddle fin. The fin 103F may increase the channel width and improve the electrical characteristics.

According to another embodiment of the present invention, the fin 103F may be omitted.

The first and second doped regions 109, 110 may be formed in the active region 103. The first doped region 109 may be formed in the active region 103 on a first side of the buried gate structure 100G, and the second doped region 110 may be formed in the active region 103 on a second side of the buried gate structure 100G.

The first and second doped regions 109, 110 may be doped with a conductive dopant. For example, the conductive dopant may include phosphorus (P), arsenic (As), antimony (Sb), or boron (B). The first and second doped regions 109, 110 may be doped with dopants of the same conductivity type. The first and second doped regions 109, 110 may be disposed in the active regions 103 on both sides of the trench 105. The first and second doped regions 109 and 110 may be spaced apart from each other by the trench 105. The bottom surfaces of the first and second doped regions 109, 110 may be disposed at a predetermined depth from the top surface of the active region 103. The bottom surfaces of the first and second doped regions 109, 110 may be higher than the bottom surface of the trench 105. The first doped region 109 may also be referred to as the ‘first source/drain region 109’, and the second doped region 110 may also be referred to as the ‘second source/drain region 110’. The buried gate structure 100G may define a channel between the first and second doped regions 109, 110. The channel may be defined along the profile of the trench 105.

The buried gate structure 100G may be embedded in the trench 105. The buried gate structure 100G may be disposed in the active region 103 between the first and second doped regions 109, 110 and may extend into the isolation layer 102. In the buried gate structure 100G, the bottom surface of the portion disposed in the active region 103 and the bottom surface of the portion disposed in the isolation layer 102 may be disposed at different levels. When the fin region 103F is omitted, the buried gate structure 100G may have the bottom surface of the portion disposed in the active region 103 and the bottom surface of the portion disposed in the isolation layer 102 disposed at the same level.

The buried gate structure 100G may include a gate dielectric layer 106 covering the bottom surface and sidewalls of the trench 105, and a gate electrode 107 and a capping layer 108 that are sequentially stacked over the gate dielectric layer 106 to fill the trench 105. The gate electrode 107 may also be referred to as a ‘buried conductive layer 107.’

The gate dielectric layer 106 may be formed conformally on the bottom and inner surfaces of the trench 105. The gate dielectric layer 106 may include silicon oxide, silicon nitride, silicon oxynitride, a high-k material, or a combination thereof. The high-k material may include a material whose dielectric constant is greater than that of silicon oxide. For example, the high-k material may include a material whose dielectric constant is greater than approximately 3.9. For another example, the high-k material may include a material whose dielectric constant is greater than approximately 10. For yet another example, the high-k material may include a material whose dielectric constant ranges from approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may optionally be used. The gate dielectric layer 106 may include a metal oxide.

The gate electrode 107 may have a shape that fills the bottom portion of the trench 105. The gate electrode 107 may include a low-resistance material to lower the gate sheet resistance. The gate electrode 107 may include a semiconductor material, a metal-based material, or a combination thereof. The gate electrode 107 may include polysilicon, a metal, a metal nitride, or a combination thereof. For example, the gate electrode 107 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present invention, the gate electrode 107 may be formed of titanium nitride alone or molybdenum alone. According to yet another embodiment of the present invention, the gate electrode 107 may be formed of a stack of titanium nitride and tungsten (i.e., TiN/W) or a stack of titanium nitride and polysilicon (i.e., TiN/Polysilicon).

According to another embodiment of the present invention, the gate electrode 107 may have a dual gate structure including upper and lower gates. According to yet another embodiment of the present invention, the gate electrode 107 may have a triple gate structure including an upper gate, a middle gate, and a lower gate.

According to another embodiment of the present invention, the gate electrode 107 may have a high work function. Here, the high work function refers to a work function that is higher than the mid-gap work function of silicon. A low work function refers to a work function that is lower than the mid-gap work function of silicon. To be specific, the high work function may have a work function which is higher than approximately 4.5 eV, and the low work function may have a work function which is lower than approximately 4.5 eV. The gate electrode 107 may include P-type polysilicon or nitrogen-rich titanium nitride (TiN).

According to another embodiment of the present invention, the gate electrode 107 may have an increased high work function. The gate electrode 107 may include a metal silicon nitride. The metal silicon nitride may be obtained by doping a metal nitride with silicon. The gate electrode 107 may include a metal silicon nitride with a controlled silicon content. For example, the gate electrode 107 may include tantalum silicon nitride (TaSiN) or titanium silicon nitride (TiSiN). Titanium nitride may have a high work function, and to further increase the work function of titanium nitride, titanium nitride may contain silicon. The titanium silicon nitride may have a controlled silicon content to have an increased high work function. According to another embodiment of the present invention, the gate electrode 107 may include titanium aluminum nitride (TiAlN).

The capping layer 108 may protect the gate electrode 107. The capping layer 108 may fill the top portion of the trench 105 over the gate electrode 107. The top surface of the capping layer 108 may be disposed at a higher level than the top surfaces of the first and second doped regions 109 and 110. According to another embodiment of the present invention, the capping layer 108 may be disposed at the same level as the top surfaces of the first and second doped regions 109 and 110. The capping layer 108 may include a dielectric material. The capping layer 108 may include silicon nitride, silicon oxynitride, or a combination thereof. According to another embodiment of the present invention, the capping layer 108 may include a combination of silicon nitride and silicon oxide. The capping layer 108 may include a silicon nitride liner and a Spin-On-Dielectric (SOD) material.

Referring to FIGS. 1A and 1B, the semiconductor device 100 may include a plurality of memory cells, and the neighboring memory cells may be isolated from each other by the isolation layer 102. One memory cell may be formed over one active region 103, and this may also be referred to as a ‘memory cell of a 1G1A (one gate-one active region) structure.’ In the memory cell of the 1G1A structure, the bit line BL may be coupled to one active region 103, so one memory cell may be coupled to one bit line BL. A memory cell of the 1G1A structure may include 1T1C (one transistor-one capacitor). As a comparative example, in a typical DRAM, two memory cells may be formed in one active region, and two gate electrodes may be formed in one active region, and two neighboring memory cells may share one bit line.

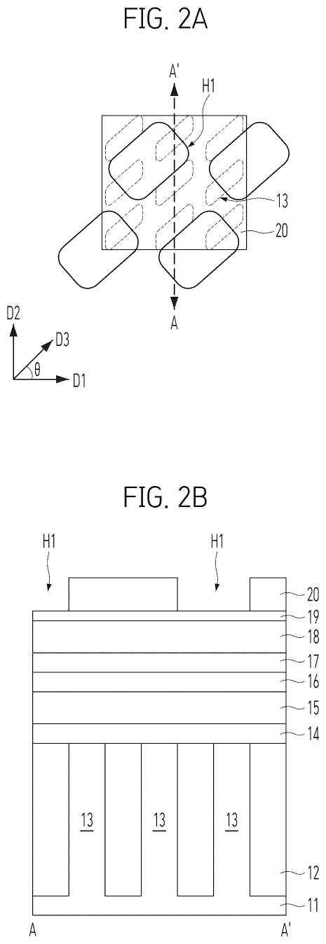

FIGS. 2A, 3A, 4A, 5A, 6A, 7A, 8A, 9A, 10A, 11A, 12A, 13A, 14A and 15A are plan views illustrating a method for fabricating a semiconductor device having a wave-shaped pattern in accordance with an embodiment of the present invention. FIGS. 2B, 3B, 4B, 5B, 6B, 7B, 8B, 9B, 10B, 11B, 12B, 13B, 14B and 15B are cross-sectional views illustrating a method for fabricating a semiconductor device having a wave-shaped pattern in accordance with an embodiment of the present invention. FIGS. 2A and 2B show the same process operation, and FIG. 2B is a cross-sectional view taken along a line A-A′ shown in in FIG. 2A.

Referring to FIGS. 2A and 2B, active regions 13 may be defined by forming an isolation layer 12 in a substrate 11.

Subsequently, a first hard mask layer 14 may be formed over the substrate 11. The first hard mask layer 14 may include a material having an etch selectivity with respect to the substrate 11. The first hard mask layer 14 may include a dielectric material. The first hard mask layer 14 may include an oxide material. For example, the first hard mask layer 14 is an Ultra Low Temperature Oxide (ULTO and may include SiO₂.

Subsequently, first and second etch auxiliary layers 15 and 16 may be sequentially formed over the first hard mask layer 14. The first hard mask layer 14 and the first and second etch auxiliary layers 15 and 16 may serve as an etch barrier for etching the substrate 11 in a subsequent process. The first and second etch auxiliary layers 15 and 16 may include a material having an etch selectivity with respect to the first hard mask layer 14. The first etch auxiliary layer 15 may include a carbon-based material. The first etch auxiliary layer 15 may be formed by a coating or deposition process. For example, the first etch auxiliary layer 15 may include Spin-On-Carbon (SOC) or amorphous carbon ACL. The second etch auxiliary layer 16 may include a nitride material. The second etch auxiliary layer 16 may be a composite containing at least one among Si, O, and N. For example, the second etch auxiliary layer 16 may include one among silicon oxynitride (SiON), silicon nitride (SiₓN_{y} (e.g., Si₃N₄)), and amorphous silicon. The thickness of the first etch auxiliary layer 15 may be thicker than the thickness of the second etch auxiliary layer 16. The thickness of the first etch auxiliary layer 15 may be approximately two times, or approximately three times greater than the thickness of the second etch auxiliary layer 16. For example, when the thickness of the first etch auxiliary layer 15 is approximately 1300 Å, the thickness of the second etch auxiliary layer 16 may be approximately 400 Å, but the embodiments of the present invention are not limited thereto.

Subsequently, the second hard mask layer 17 may be formed over the second etch auxiliary layer 16. The second hard mask layer 17 may be used to define a sacrificial wave-shaped pattern through the subsequent process of repeatedly etching a hole pattern. The second hard mask layer 17 may have an etch selectivity with respect to the second etch auxiliary layer 16. The second hard mask layer 17 may be a composite containing at least one of Si, O, N, and C. For example, the second hard mask layer 17 may include one of polysilicon, amorphous silicon, and silicon nitride (SiN). The second hard mask layer 17 may be formed at a deposition temperature of approximately 400° or lower. The second hard mask layer 17 may have a thickness which is greater than the thickness of the second etch auxiliary layer 16, but the embodiments of the present invention are not limited thereto.

Subsequently, third and fourth etch auxiliary layers 18 and 19 may be sequentially formed over the second hard mask layer 17. The third and fourth etch auxiliary layers 18 and 19 may include the same material as the first and second etch auxiliary layers 15 and 16, respectively. For example, the third etch auxiliary layer 18 may include Spin-On-Carbon or amorphous carbon, and the fourth etch auxiliary layer 19 may include one of silicon oxynitride (SiON), silicon nitride (SiₓN_{y}, e.g., Si₃N₄), and amorphous silicon.

Subsequently, a first mask pattern 20 defining first hole pattern H1 may be formed. The first mask pattern 20 may include a photoresist PR or a metal oxide resist MOR.

The first hole pattern H1 may be tilted at the same angle as that of each active region 13. The first hole pattern H1 may be formed through a patterning process using extreme ultraviolet lithography (EUV). The ends of the first hole patterns H1 may be aligned in the first direction D1 and may be spaced apart from each other at regular intervals. The first hole patterns H1 may be spaced apart from each other at regular intervals in the second direction D2, and the first hole patterns H1 arranged in the second direction D2 may be arranged in a zigzag shape.

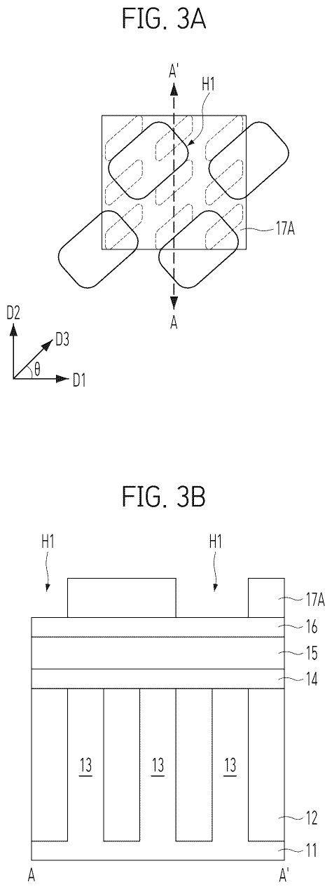

Referring to FIGS. 3A and 3B, a second hard mask pattern 17A in which the first hole pattern H1 is defined may be formed. The second hard mask pattern 17A may be formed through a series of processes of sequentially etching the fourth etch auxiliary layer 19 and the third etch auxiliary layer 18 by using the first mask pattern 20, and then etching the second hard mask layer 17 (see FIG. 2A).

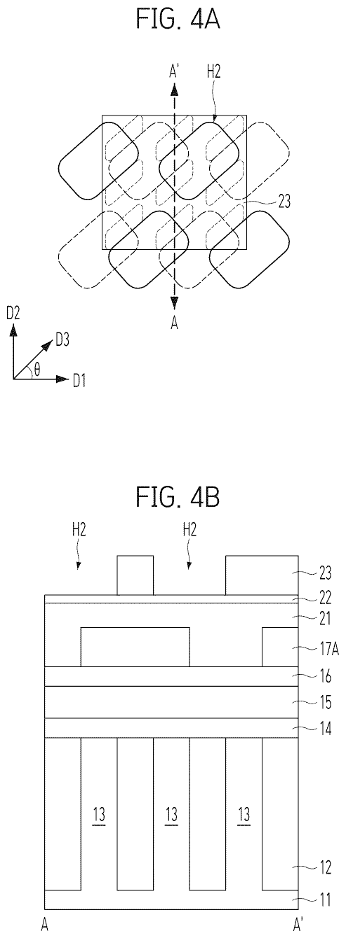

Referring to FIGS. 4A and 4B, fifth and sixth etch auxiliary layers 21 and 22 may be sequentially formed over the second hard mask pattern 17A and the second etch auxiliary layer 16.

The fifth etch auxiliary layer 21 may include the same material as that of the third etch auxiliary layer 15. The fifth etch auxiliary layer 21 may also be referred to as a ‘planarization layer.’ The sixth etch auxiliary layer 22 may include the same material as that of the fourth etch auxiliary layer 16.

Subsequently, a second mask pattern 23 in which the second hole pattern H2 is defined may be formed over the sixth etch auxiliary layer 22. The second mask pattern 23 may include a photoresist PR or a metal oxide resist MOR.

The second hole pattern H2 may have the same size as that of the first hole pattern H1. The second hole pattern H2 may be patterned by using the same reticle as that of the first hole pattern H1. The ends of the second hole patterns H2 may be aligned in the first direction D1 and may be spaced apart from each other at regular intervals. The second hole patterns H2 may be spaced apart from each other at regular intervals in the second direction D2, and the second hole patterns H2 arranged in the second direction D2 may be arranged in a zigzag shape.

The ends of the second hole pattern H2 may be aligned with the first hole pattern H1 in the first direction D1. The second hole pattern H2 may partially overlap with the first hole pattern H1 in the first direction D1.

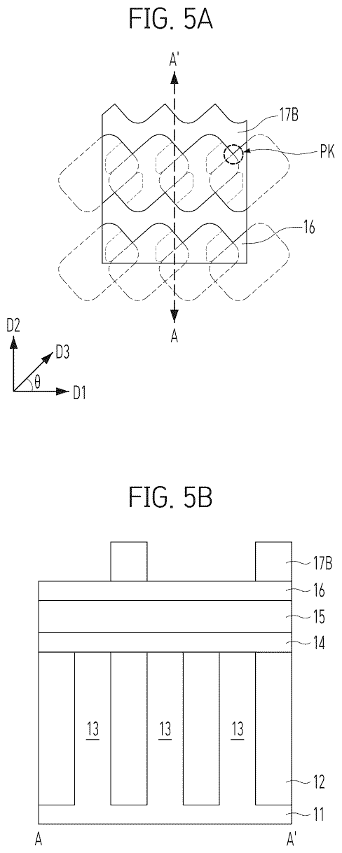

Referring to FIGS. 5A and 5B, a second hard mask pattern 17B may be formed defining a sacrificial wave-shaped pattern. The second hard mask pattern 17B may define the sacrificial wave-shaped pattern extending in the first direction D1. The second hard mask pattern 17B may be formed through a series of processes of sequentially etching the sixth etch auxiliary layer 22 and the fifth etch auxiliary layer 21 by using the second mask pattern 23 and then etching the second hard mask pattern 17A (see FIG. 4B) by using the etched fifth and sixth etch auxiliary layers 21 and 22. While the second hard mask pattern 17B is etched, the second etch auxiliary layer 16 may remain without being lost due to the etch selectivity.

The second hard mask pattern 17B may have a peak point PK in an area where the first and second hole patterns H1 and H2 overlap with each other.

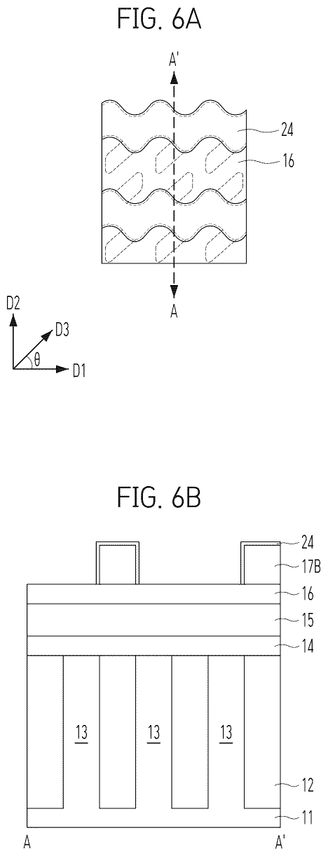

Referring to FIGS. 6A and 6B, the surface of the second hard mask pattern 17B may be oxidized to form a sacrificial oxide layer 24 on the surface of the second hard mask pattern 17B.

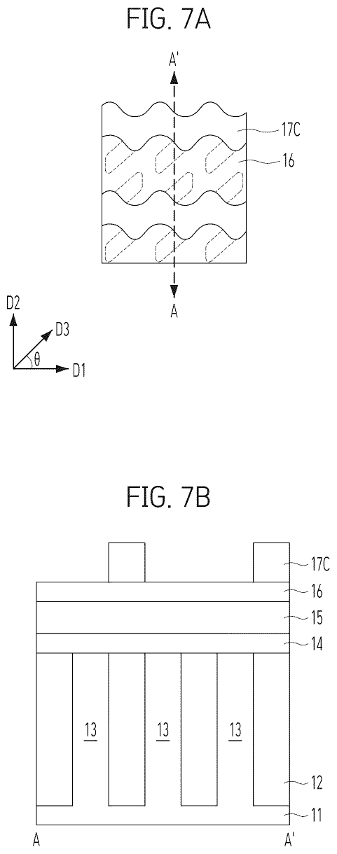

Referring to FIGS. 7A and 7B, the sacrificial oxide layer 24 (see FIG. 6B) may be removed. The second hard mask pattern 17B (see FIG. 6B) which the sacrificial oxide layer 24 (see FIG. 6B) has been removed is referred to as the “second hard mask pattern 17C”. As a result, a second hard mask pattern 17C having a sacrificial wave-shaped pattern from which the peak point PK (see FIG. 5A) is removed may be formed. The second hard mask pattern 17C may be referred to as a ‘sacrificial pattern 17C’.

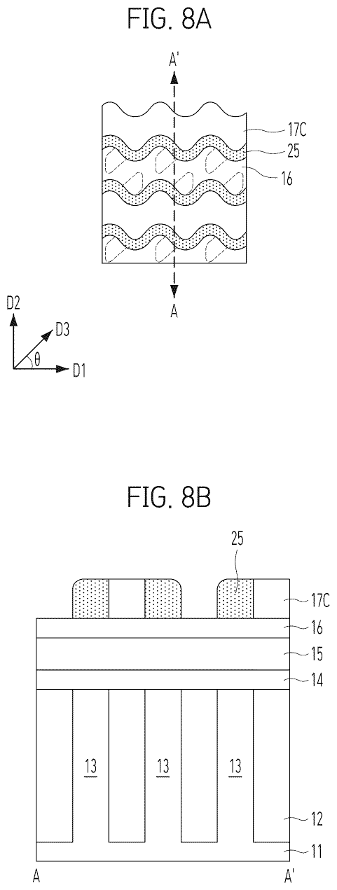

Referring to FIGS. 8A and 8B, sacrificial spacers 25 may be formed on both sides of the second hard mask pattern 17C. The sacrificial spacers 25 may include a material having an etch selectivity with respect to the second hard mask pattern 17C. The sacrificial spacers 25 may include a material having excellent step coverage. The sacrificial spacers 25 may be formed by Atomic Layer Deposition (ALD) to maintain a uniform thickness. The sacrificial spacers 25 may be formed through a series of processes of forming a dielectric material to cover the second hard mask pattern 17C and performing a spacer etching process. The sacrificial spacers 25 may be wave-shaped patterns extending in the first direction D1, just like the second hard mask patterns 17C. Although not illustrated, the sacrificial spacers 25 may be coupled to both ends of the second hard mask pattern 17C extending in the first direction D1. For example, the sacrificial spacers 25 may be shaped to surround the sidewall of the second hard mask pattern 17C. Just like the second hard mask patterns 17C, the sacrificial spacers 25 may be a composite containing at least one of Si, O, N, and Ti. For example, the sacrificial spacers 25 may include silicon oxide (SiO₂), which is an ultra-low temperature oxide (ULTO), or titanium nitride (TiN).

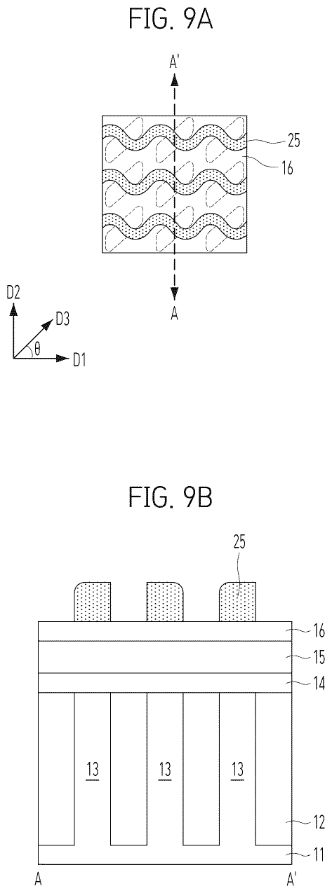

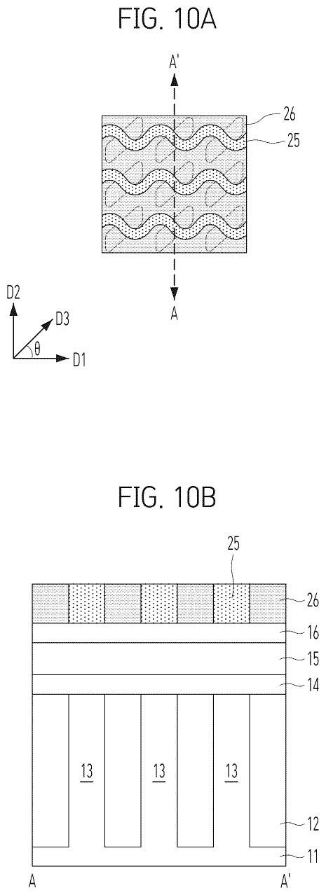

Referring to FIGS. 9A and 9B, the second hard mask pattern 17C (see FIG. 8B) may be removed. As a result, the sacrificial spacers 25 having a wave-shaped pattern may remain. The second etch auxiliary layer 16 may be exposed between the sacrificial spacers 25.

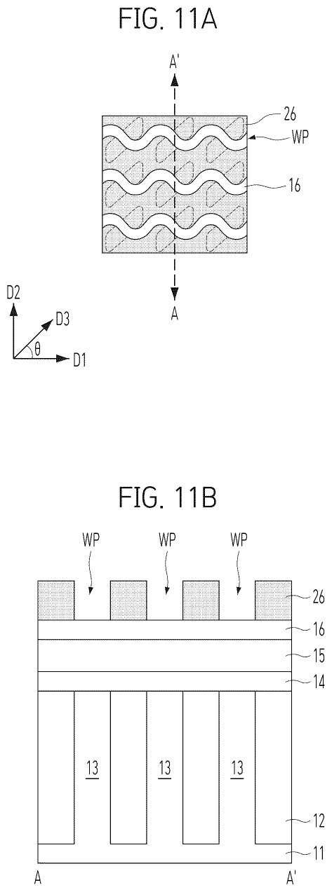

Referring to FIGS. 10A and 10B, a third hard mask pattern 26 may be formed to fill the gap between the sacrificial spacers 25. The third hard mask pattern 26 may serve as an etch barrier to etch a lower layer. The third hard mask pattern 26 may include a material having an etch selectivity with respect to the sacrificial spacers 25. The third hard mask pattern 26 may include a silicon material. The third hard mask pattern 26 may be a composite containing at least one of Si, O, N, and C. For example, the third hard mask pattern 26 may include one of polysilicon, amorphous silicon, and silicon nitride (SiN).

Referring to FIGS. 11A and 11B, the sacrificial spacers 25 (see FIG. 10B) may be removed, for example, by a wet etching process. As a result, the wave-shaped pattern WP may be defined by the third hard mask pattern 26. The second etch auxiliary layer 16 may be exposed between the third hard mask patterns 26. According to another embodiment of the present invention, the line width of the wave-shaped pattern WP may be smaller than the line width of the third hard mask pattern 26. The line width of the wave-shaped pattern WP may be adjusted through the line width of the sacrificial spacers 25 or the line width of the third hard mask pattern 26, if needed.

Subsequently, the third hard mask pattern 26 may be etched by using a cut mask. The cut mask may etch the wave-shaped pattern at the end of the memory cell region. For example, when the ends of the third hard mask pattern 26 are continued to each other, they may be etched and separated through the cut mask.

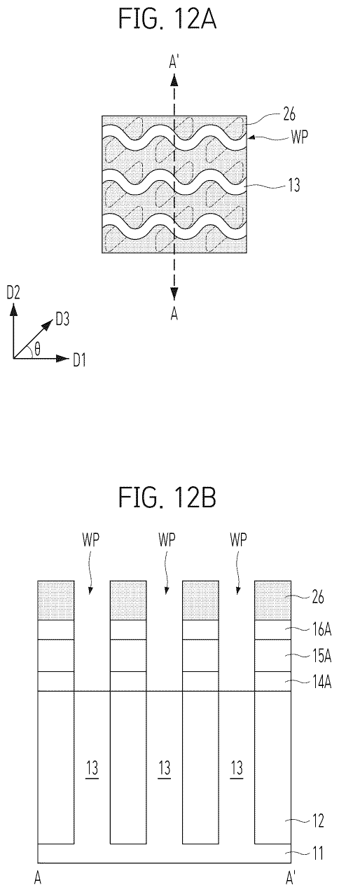

Referring to FIGS. 12A and 12B, hard mask structures 14A, 15A, and 16A defining a wave-shaped pattern WP may be formed. The hard mask structures 14A, 15A, and 16A may include a stacked structure of a first hard mask pattern 14A and first and second etch auxiliary patterns 15A and 16A. The hard mask structures may be formed through a series of processes of sequentially etching the second etch auxiliary layer 16 (see FIG. 11B), the first etch auxiliary layer 15 (see FIG. 11B), and the first hard mask layer 14 (see FIG. 11B) by using the third hard mask pattern 26.

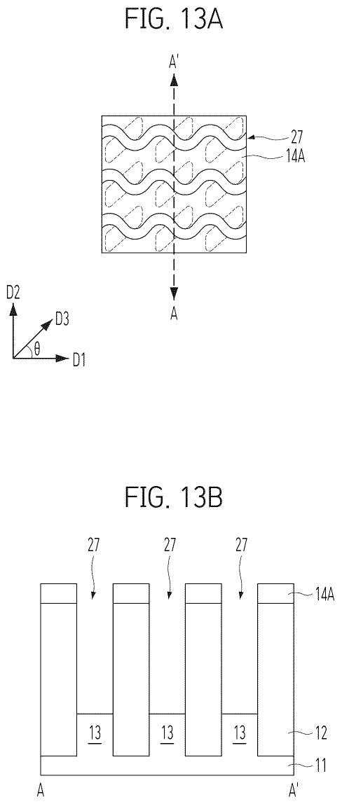

Referring to FIGS. 13A and 13B, a trench 27 having a wave- shaped pattern extending in the first direction D1 may be formed by using the hard mask structures 14A, 15A and 16A (see FIG. 12B) and the third hard mask pattern 26 as an etch barrier and etching the substrate 11. The trench 27 may be a wave-shaped pattern crossing the active regions 13 and the isolation layer 12. In particular, according to this embodiment of the present invention, the wave-shaped pattern of the trench 27 may extend with a uniform line width. The trench 27 may cross the center of each active region 13.

The wave-shaped pattern of the trench 27 may have a tilting angle that may maximize the area of the active regions 13 exposed on both sides of the trench 27. For example, the wave-shaped pattern of the trench 27 overlapping with each active region 13 may have a tilting angle of approximately 45° to 135° based on the long axis of each active region 13.

The trenches 27 may be spaced apart from each other in the second direction D2. The trench 27 may have a shallower depth than the isolation layer 12. The trench 27 may be a space where a buried gate structure is formed, and the trench 27 may also be referred to as a ‘gate trench 27’.

During the process of forming the trench 27, the third hard mask pattern 26 and the second etch auxiliary pattern 16A may be lost, and when the process of forming the trench 27 is completed, the first hard mask pattern 14A and the first etch auxiliary pattern 15A may remain over the substrate 11.

Subsequently, the first etch auxiliary pattern 15A may be removed through a strip process. The strip process may be performed as a strip process for removing a photosensitive film, that is, an oxygen strip process. As a result, the first hard mask pattern 14A may remain over the substrate 11.

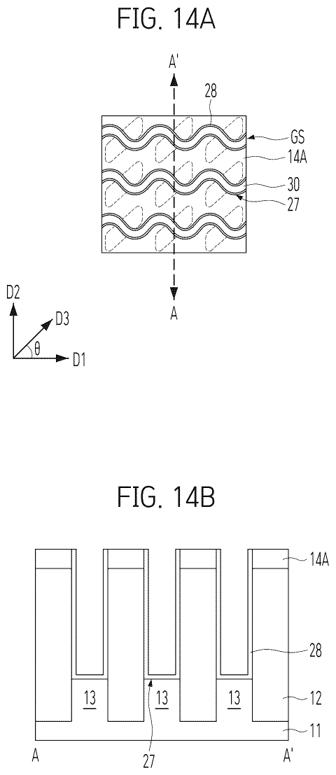

Referring to FIGS. 14A and 14B, a gate dielectric layer 28 may be formed covering the bottom surface and sidewalls of the trench 27. The gate dielectric layer 28 may be conformally formed on the bottom and inner surfaces of the trench 27. The gate dielectric layer 28 may include silicon oxide, silicon nitride, silicon oxynitride, a high-k material, or a combination thereof. The high-k material may include a material whose dielectric constant is greater than that of silicon oxide. For example, the high-k material may include a material whose dielectric constant is greater than approximately 3.9. For another example, the high-k material may include a material whose dielectric constant is greater than approximately 10. For yet another example, the high-k material may include a material whose dielectric constant ranges from approximately 10 to 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present invention, the high-k material may include lanthanum oxide, lanthanum aluminum oxide, zirconium oxide, zirconium silicon oxide, and zirconium silicon oxynitride, aluminum oxide, or a combination thereof. As for the high-k material, other known high-k materials may optionally be used. The gate dielectric layer 28 may include a metal oxide.

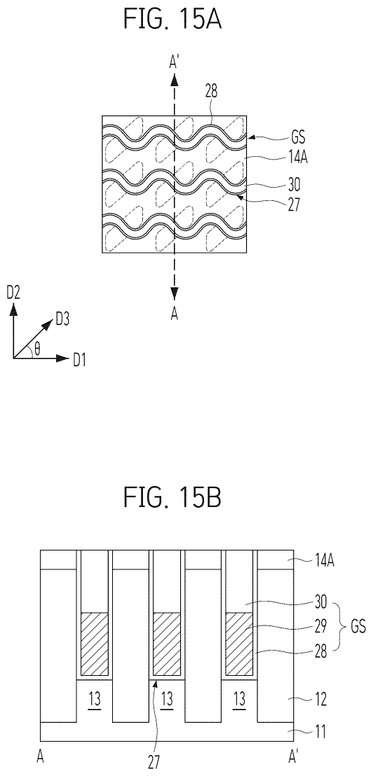

Referring to FIGS. 15A and 15B, buried gate structure GS may be formed by sequentially forming the gate electrode 29 and the capping layer 30 over the gate dielectric layer 28.

The gate electrode 29 may fill a bottom portion of the trench 27. The gate electrode 29 may include a low-resistance material to lower the gate sheet resistance. The gate electrode 29 may include a semiconductor material, a metal-based material, or a combination thereof. The gate electrode 29 may include polysilicon, a metal, a metal nitride, or a combination thereof. For example, the gate electrode 29 may include N-type doped polysilicon, tantalum nitride (TaN), titanium nitride (TiN), tungsten (W), tungsten nitride (WN), molybdenum (Mo), ruthenium (Ru), or a combination thereof. According to another embodiment of the present invention, the gate electrode 29 may be formed of titanium nitride alone or molybdenum alone. According to yet another embodiment of the present invention, the gate electrode 29 may be formed of a stack of titanium nitride and tungsten (i.e., TiN/W) or a stack of titanium nitride and polysilicon (i.e., TiN/Polysilicon).

According to another embodiment of the present invention, the gate electrode 29 may have a dual gate structure including upper and lower gates. According to yet another embodiment of the present invention, the gate electrode 29 may have a triple gate structure including an upper gate, a middle gate, and a lower gate.

According to another embodiment of the present invention, the gate electrode 29 may have a high work function. Here, the high work function refers to a work function that is higher than the mid-gap work function of silicon. A low work function refers to a work function that is lower than the mid-gap work function of silicon. For example, the high work function may have a work function that is higher than approximately 4.5 eV, and the low work function may have a work function that is lower than approximately 4.5 eV. The gate electrode 29 may include P-type polysilicon or nitrogen-rich titanium nitride (TiN).

According to another embodiment of the present invention, the gate electrode 29 may have an increased high work function. The gate electrode 29 may include a metal silicon nitride. The metal silicon nitride may be obtained by doping a metal nitride with silicon. The gate electrode 29 may include a metal silicon nitride with a controlled silicon content. For example, the gate electrode 29 may include tantalum silicon nitride (TaSiN) or titanium silicon nitride (TiSiN). Titanium nitride may have a high work function, and the titanium nitride may contain silicon in order to further increase the work function of titanium nitride. As for the titanium silicon nitride, the content of silicon may be adjusted to have an increased high work function. According to another embodiment of the present invention, the gate electrode 29 may include titanium aluminum nitride (TiAlN).

The capping layer 30 may protect the gate electrode 29. The capping layer 30 may fill the top portion of the trench 27 over the gate electrode 29. The top surface of the capping layer 30 may be disposed at the same level as the top surface of the first hard mask pattern 14A. The capping layer 30 may include a dielectric material. The capping layer 30 may include silicon nitride, silicon oxynitride, or a combination thereof. According to another embodiment of the present invention, the capping layer 30 may include a combination of silicon nitride and silicon oxide. The capping layer 30 may include a silicon nitride liner and a Spin-On-Dielectric (SOD) material.

As described above, according to this embodiment of the present invention, a wave-shaped pattern having a uniform line width may be formed by repeatedly applying a hole pattern that is patterned by using extreme ultraviolet (EUV). As a comparative example, when a wave-shaped pattern is directly formed by using extreme ultraviolet rays (EUV), there is a problem in that it is difficult to apply the wave-shaped pattern to the process due to poor curvature distribution.

Although this embodiment describes a buried gate structure to which a wave-shaped pattern is applied, it may also be applied to the process of forming a conductive line that requires a wave-shaped pattern, such as a bit line, in addition to the buried gate structure according to another embodiment of the present invention.

This embodiment describes a buried gate structure in which a wave-shaped pattern is applied to the active region of a 1G1A structure, but it may also be applied to a buried gate structure of 6F2 according to another embodiment of the present invention.

Also, according to this embodiment of the present invention, the hole pattern is applied twice, but according to another embodiment of the present invention, it is possible to apply the hole pattern more than twice, if needed.

Also, according to this embodiment of the present invention the sacrificial spacers are applied once, but according to another embodiment of the present invention, it is also possible to form a finer wave-shaped pattern by applying the sacrificial spacers more than once, if needed.

Also, positive spacer patterning is applied according to this embodiment of the present invention, but negative spacer patterning may be applied according to another embodiment of the present invention. When the negative spacer patterning is applied, the third hard mask pattern 26 (see FIG. 10B) that fills the gap between the sacrificial spacers may be omitted.

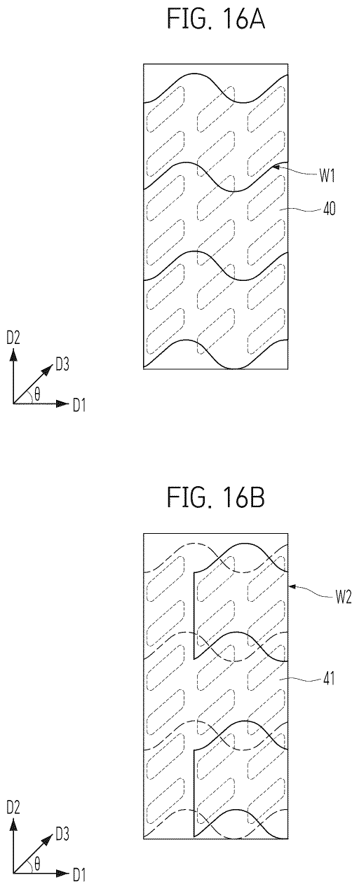

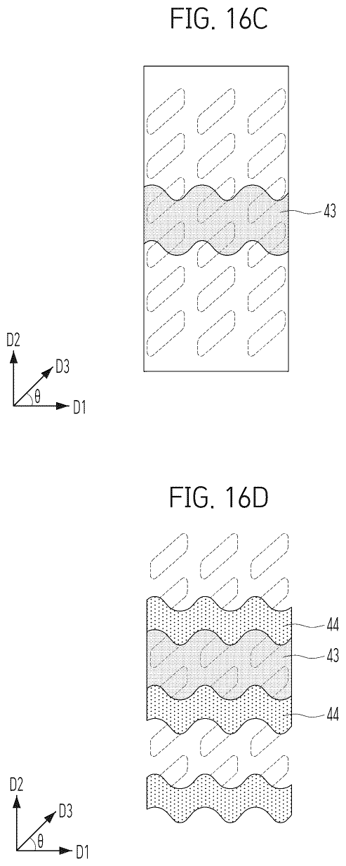

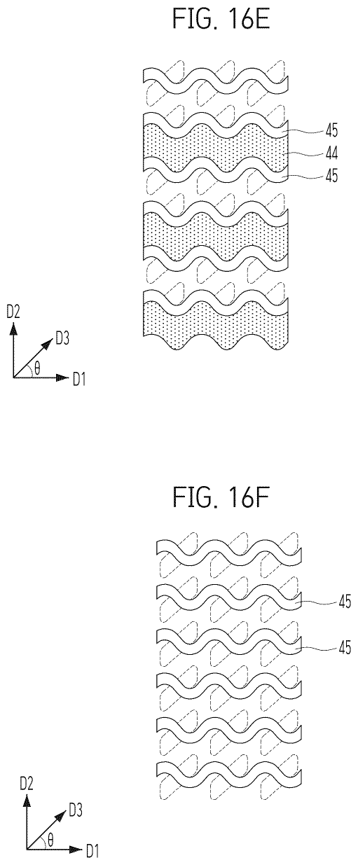

FIGS. 16A to 16F are plan views illustrating a method for forming a wave-shaped pattern in accordance with another embodiment of the present invention. FIGS. 16A to 16F illustrate the process of forming the sacrificial wave-shaped pattern up to the process of FIG. 9A. After the process of FIG. 16F, the processes of FIGS. 10A to 15A may be further performed to form a semiconductor device.

Referring to FIG. 16A, a first mask pattern 40 defining a first initial wave-shaped pattern W1 may be formed. The first initial wave-shaped patterns W1 may extend in the first direction D1 and may be spaced apart in the second direction D2. The first initial wave-shaped pattern W1 may expose at least two active regions arranged in the second direction, but the embodiments of the present invention are not limited thereto. The first mask pattern 40 may be patterned by using ArF. The first mask pattern 40 may include a photoresist.

Referring to FIG. 16B, a second mask pattern 41 defining the second initial wave-shaped pattern W2 may be formed. The second initial wave-shaped patterns W2 may extend in the first direction D1 and may be spaced apart from each other in the second direction D2. The second initial wave-shaped pattern W2 may have the same shape as that of the first initial wave-shaped pattern W1 and may have a shape moved by a predetermined distance in the first direction D1. The second mask pattern 41 may be patterned by using the same reticle as that of the first mask pattern 40.

Referring to FIG. 16C, a third initial wave-shaped pattern layer 43 may be formed. The third initial wave-shaped pattern layer 43 may be formed through an etching process using the first and second mask patterns 40 and 41.

Referring to FIG. 16D, first sacrificial spacers 44 may be formed on both sidewalls of the third initial wave-shaped pattern layer 43, and subsequently the third initial wave-shaped pattern layer 43 may be removed.

Referring to FIG. 16E, second sacrificial spacers 45 may be formed on both sidewalls of the first sacrificial spacers 44.

Referring to FIG. 16F, the first sacrificial spacers 44 may be removed while the second sacrificial spacers 45 defining the sacrificial wave-shaped pattern may remain.

Subsequently, the processes of FIGS. 10A to 15A may be performed to form a semiconductor device.

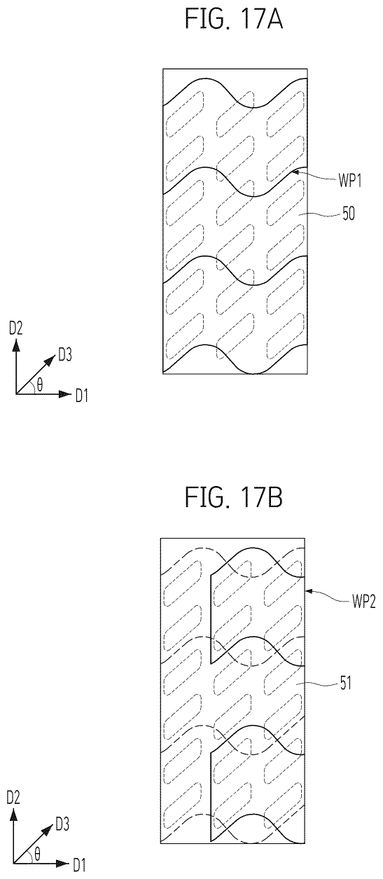

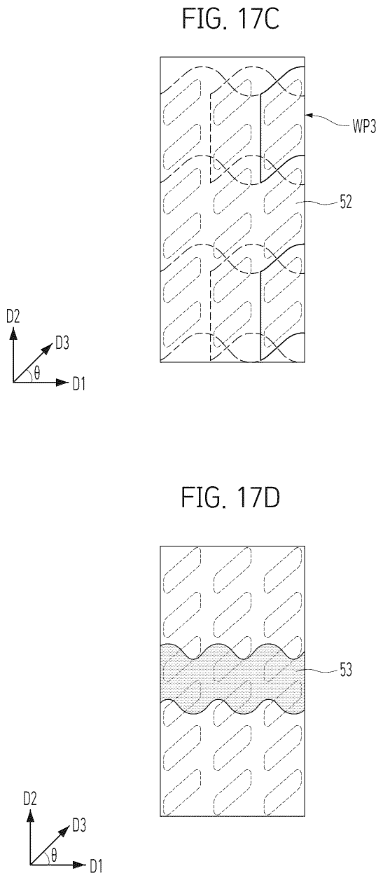

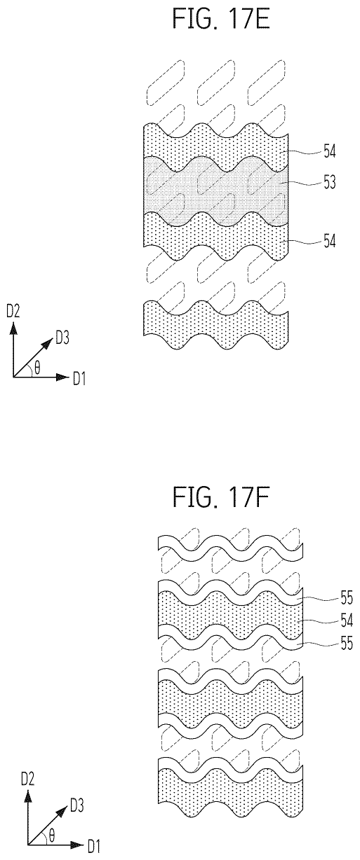

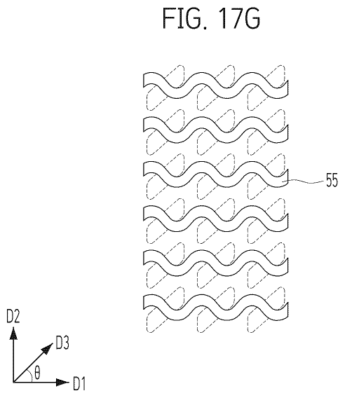

FIGS. 17A to 17G are plan views illustrating a method for forming a wave-shaped pattern in accordance with yet another embodiment of the present invention. FIGS. 17A to 17G illustrate the process for forming the sacrificial wave-shaped pattern up to the process of FIG. 9A. After the process of FIG. 17G, the processes of FIGS. 10A to 15A may be further performed to form a semiconductor device.

Referring to FIG. 17A, a first mask pattern 50 defining the first initial wave-shaped pattern WP1 may be formed. The first initial wave-shaped patterns WP1 may extend in the first direction D1 and may be spaced apart from each other in the second direction D2. The first initial wave-shaped pattern WP1 may expose at least two active regions that are arranged in the second direction, but the embodiments of the present invention are not limited thereto. The first mask pattern 50 may be patterned by using ArF. The first mask pattern 50 may include a photoresist.

Referring to FIG. 17B, a second mask pattern 51 defining a second initial wave-shaped pattern WP2 may be formed. The second initial wave-shaped patterns WP2 may extend in the first direction D1 and may be spaced apart from each other in the second direction D2. The second initial wave-shaped pattern WP2 may have the same shape as that of the first initial wave-shaped pattern WP1 and may have a shape moved by a predetermined distance in the first direction D1. The second mask pattern 51 may be patterned by using the same reticle as that of the first mask pattern 50.

Referring to FIG. 17C, a third mask pattern 52 defining third initial wave-shaped patterns WP3 may be formed. The third initial wave-shaped patterns WP3 may extend in the first direction D1 and may be spaced apart from each other in the second direction D2. The third initial wave-shaped patterns WP3 may have the same shape as those of the first initial wave-shaped patterns WP1 and the second initial wave-shaped patterns WP2 and may have a shape moved by a predetermined distance in the first direction D1. The third mask pattern 52 may be patterned by using the same reticle as that of the first mask pattern 50.

Referring to FIG. 17D, a fourth initial wave-shaped pattern layer 53 may be formed. The third initial wave-shaped pattern layer 53 may be formed through an etching process using the first to third mask patterns 50, 51 and 52.

Referring to FIG. 17E, first sacrificial spacers 54 may be formed on both sidewalls of the fourth initial wave-shaped pattern layer 53.

Subsequently, the third initial wave-shaped pattern layer 53 may be removed.

Referring to FIG. 17F, second sacrificial spacers 55 may be formed on both sidewalls of the first sacrificial spacers 54.

Referring to FIG. 17G, the first sacrificial spacers 54 may be removed while the second sacrificial spacers 55 defining the sacrificial wave-shaped pattern remain.

Subsequently, the processes of FIGS. 10A to 15A may be performed to form a semiconductor device.

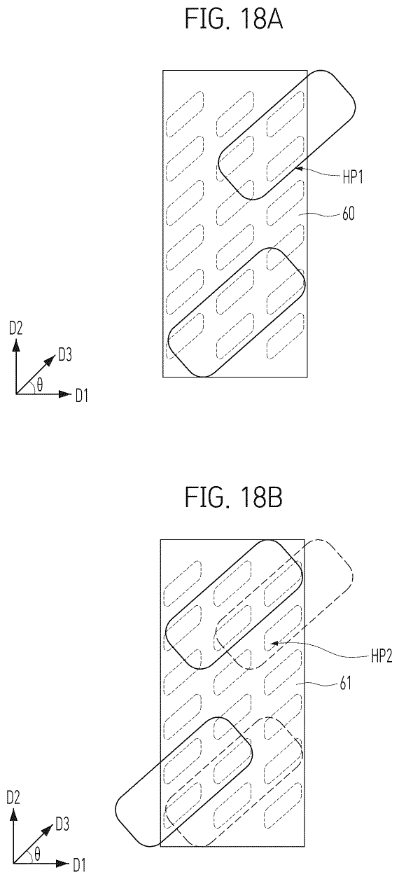

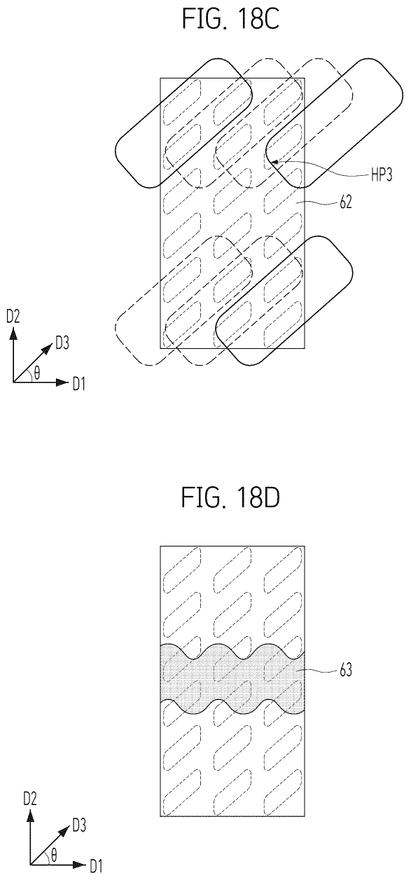

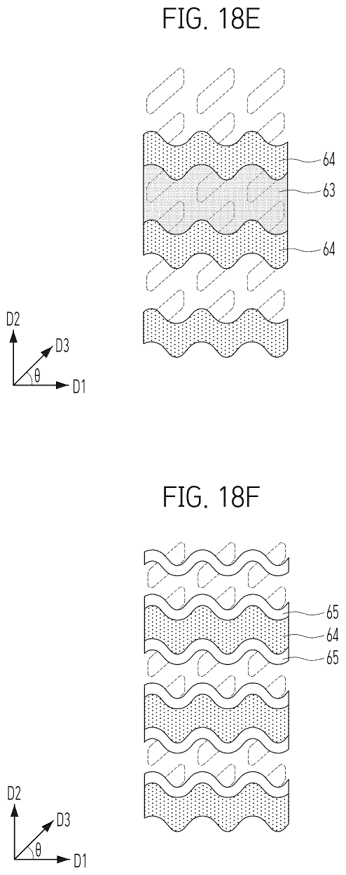

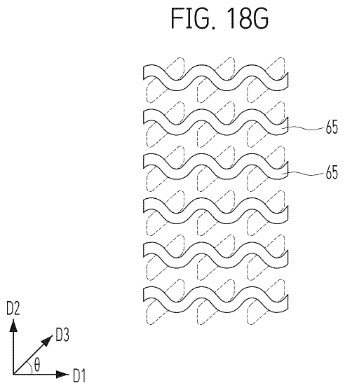

FIGS. 18A to 18G are plan views illustrating a method for forming a wave-shaped pattern in accordance with yet another embodiment of the present invention. FIGS. 18A to 18G illustrate the process for forming the sacrificial wave-shaped pattern up to the process of FIG. 9A. After the process of FIG. 18G, the processes of FIGS. 10A to 15A may be further performed to form a semiconductor device.

Referring to FIG. 18A, a first mask pattern 60 defining a first hole pattern HP1 may be formed. The first hole pattern HP1 may be tilted at the same angle as that of the active region. The first hole pattern HP1 may be formed through a patterning process using extreme ultraviolet lithography (EUV). The ends of the first hole patterns HP1 may be aligned in the first direction D1 and may be spaced apart from each other at regular intervals. The first hole patterns HP1 may be spaced apart from each other at regular intervals in the second direction D2, and the first hole patterns HP1 arranged in the second direction D2 may be arranged in a zigzag shape. The first mask pattern 60 may be patterned by using ArF. The first mask pattern 60 may include a photoresist.

Referring to FIG. 18B, a second mask pattern 61 defining a second hole pattern HP2 may be formed. The second hole patterns HP2 may extend in the first direction D1 and may be spaced apart from each other in the second direction D2. The second hole pattern HP2 may have the same shape as that of the first hole pattern HP1 and may have a shape moved by a predetermined distance in the first direction D1. The second mask pattern 61 may be patterned by using the same reticle as that of the first mask pattern 60.

Referring to FIG. 18C, a third mask pattern 62 defining a third hole pattern HP3 may be formed. The third hole patterns HP3 may extend in the first direction D1 and may be spaced apart from each other in the second direction D2. The third hole pattern HP3 may have the same shape as that of the second hole pattern HP2 and may have a shape moved by a predetermined distance in the first direction D1. The third mask pattern 62 may be patterned by using the same reticle as that of the first mask pattern 60.

Referring to FIG. 18D, an initial wave-shaped pattern layer 63 may be formed. The initial wave-shaped pattern layer 63 may be formed through an etching process using the first to third mask patterns 60, 61 and 62.

Referring to FIG. 18E, first sacrificial spacers 64 may be formed on both sidewalls of the initial wave-shaped pattern layer 63.

Subsequently, the initial wave-shaped pattern layer 63 may be removed.

Referring to FIG. 18F, second sacrificial spacers 65 may be formed on both sidewalls of the first sacrificial spacers 64.

Referring to FIG. 18G, the first sacrificial spacers 64 may be removed. As a result, the second sacrificial spacers 65 defining the sacrificial wave-shaped pattern may remain.

Subsequently, the processes of FIGS. 10A to 15A may be performed to form a semiconductor device.

According to the embodiments of the present invention, it is possible to minimize process difficulty and an increase in the process costs when applying a fine wave-shaped pattern.

According to the embodiment of the present invention, it is possible to secure the area of a contact region by applying a buried gate having a wave-shaped pattern.

While the embodiments of the present invention have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A method for fabricating a semiconductor device, the method comprising:
forming an isolation layer and an active region defined by the isolation layer in a substrate;
forming a wave-shaped sacrificial pattern extending in a first direction over the substrate;
forming sacrificial spacers on both sides of the sacrificial pattern;
forming a hard mask pattern to gap-fill between the sacrificial spacers;
removing the sacrificial spacers;
forming a trench crossing the isolation layer and the active region in the first direction and disposed at a center of each active region by using the hard mask pattern as an etch barrier and etching the substrate; and
forming a buried gate structure to gap-fill the trench.

2. The method of claim 1, wherein the forming of the wave-shaped sacrificial pattern includes:
forming a hard mask layer over the substrate;
forming a first mask pattern that defines a first hole pattern over the hard mask layer;
etching the hard mask layer by using the first mask pattern as an etch barrier;
forming a planarization layer over the etched hard mask layer;
forming a second mask pattern that defines a second hole pattern having a same shape as a shape of the first hole pattern and partially overlapping with the first hole pattern in the first direction over the planarization layer; and
forming the wave-shaped sacrificial pattern by using the second mask pattern as an etch barrier and etching the planarization layer and the hard mask layer.

3. The method of claim 2, wherein the first and second mask patterns are patterned by using extreme ultraviolet rays (EUV).

4. The method of claim 1, wherein the trench has a wave-shaped pattern extending in the first direction, and
the wave-shaped pattern has a tilting angle of approximately 45° to 135° based on a long axis of the active region.

5. The method of claim 2, further comprising:
before forming the first mask pattern, forming first and second etch auxiliary layers over the hard mask layer.

6. The method of claim 1, wherein the sacrificial pattern includes a composite material comprising at least one of Si, O, N, and C.

7. The method of claim 1, wherein the sacrificial pattern includes at least one of silicon, polysilicon, amorphous silicon, and silicon nitride.

8. The method of claim 1, wherein the spacers include a composite material comprising at least one of Si, O, N, and Ti.

9. The method of claim 1, wherein the spacers include silicon oxide, which is an Ultra Low Temperature Oxide (ULTO), or titanium nitride.

10. The method of claim 5, wherein the first etch auxiliary layer includes a carbon-based material.

11. The method of claim 5, wherein the first etch auxiliary layer includes Spin-On-Carbon (SOC) or amorphous carbon.

12. The method of claim 5, wherein the second etch auxiliary layer incudes a composite material comprising at least one of Si, O, and N.

13. The method of claim 5, wherein the second etch auxiliary layer includes at least one of silicon oxynitride (SiON), silicon oxide, and amorphous silicon.

14. The method of claim 1, wherein after forming the buried gate structure,
a first doped region is formed in an active region on a first side of the buried gate structure by doping the substrate with an impurity, and
a second doped region is formed in an active region on a second side of the buried gate structure.

15. A method for fabricating a semiconductor device, the method comprising:
forming an isolation layer and an active region defined by the isolation layer over a substrate;
forming a wave-shaped sacrificial pattern extending in a first direction over the substrate;
forming spacers on both sides of the sacrificial pattern;
forming a trench crossing the isolation layer and the active region in the first direction and disposed at a center of each active region by using the spacers as an etch barrier and etching the substrate; and
forming a buried gate structure gap-filling the trench.

16. A method for forming a pattern, the method comprising:
sequentially forming a first hard mask layer and a second hard mask layer over an etch target layer;
forming a first mask pattern that defines a first hole pattern over the second hard mask layer;
etching a second hard mask layer by using the first mask pattern as an etch barrier;
forming a planarization layer over the etched second hard mask layer;
forming a second mask pattern that defines a second hole pattern having a same shape as a shape of the first hole pattern and partially overlapping with the first hole pattern in a first direction over the planarization layer;
forming a second hard mask pattern having a wave-shaped pattern by using the second mask pattern as an etch barrier and etching the planarization layer and the second hard mask layer;
etching the first hard mask layer by using the second hard mask pattern as an etch barrier; and
forming a fine wave-shaped pattern by using the etched first hard mask layer as an etch barrier and etching the etch target layer.

17. A method for fabricating a semiconductor device, the method comprising:
forming an isolation layer and an active region defined by the isolation layer in a substrate;
forming a wave-shaped sacrificial pattern extending in a first direction over the substrate;
forming sacrificial spacers on both sides of the sacrificial pattern;
forming spacers on both sides of the sacrificial spacer;
forming a trench crossing the isolation layer and the active region in the first direction and disposed at a center of each active region by using the spacers as an etch barrier and etching the substrate; and
forming a buried gate structure to gap-fill the trench.

18. The method of claim 17, wherein forming the wave-shaped sacrificial pattern includes:
forming a hard mask layer over the substrate;
forming a first mask pattern that defines a first initial wave-shaped pattern extending in the first direction over the hard mask layer;
forming a second mask pattern that defines a second initial wave-shaped pattern having a same shape as a shape of the first initial wave-shaped pattern and moved by a predetermined distance in the first direction over the first mask pattern; and
etching the planarization layer and the hard mask layer by using the first and second mask patterns as an etch barrier to form the wave-shaped sacrificial pattern.

19. The method of claim 18, wherein the first and second mask patterns are patterned by using ArF.

20. The method of claim 17, wherein forming the wave- shaped sacrificial pattern includes:
forming a hard mask layer over the substrate;
forming a first mask pattern that defines a first initial wave-shaped pattern extending in the first direction over the hard mask layer;
forming a second mask pattern that defines a second initial wave-shaped pattern having the same shape as a shape of the first initial wave-shaped pattern and moved by a predetermined distance in the first direction over the first mask pattern;
forming a third mask pattern that defines a third initial wave-shaped pattern having a same shape as a shape of the second initial wave-shaped pattern and moved by a predetermined distance in the first direction over the second mask pattern; and
etching the hard mask layer by using the first to third mask patterns to form the wave-shaped sacrificial pattern.

21. The method of claim 20, wherein the first to third mask patterns are patterned by using ArF.

22. The method of claim 17, wherein forming the wave- shaped sacrificial pattern includes:
forming a hard mask layer over the substrate;
forming a first mask pattern that defines a first hole pattern over the hard mask layer;
forming a second mask pattern that defines a second hole pattern having a same shape as a shape of the first hole pattern and partially overlapping with the first hole pattern in the first direction over the first mask pattern;
forming a third mask pattern that defines a third hole pattern having the same shape as a shape of the second hole pattern and partially overlapping with the second hole pattern in the first direction over the second mask pattern; and
etching the hard mask layer by using the first to third mask patterns as an etch barrier to form the wave-shaped sacrificial pattern.

23. The method of claim 22, wherein the first to third mask patterns are patterned by using ArF.
